(19) United States
(12) Patent Application Publication
(10) Pub. No.: US 2008/0012079 A1
(43) Pub. Date: Jan. 17, 2008

(54) Memory cell having active region sized for low reset current and method of fabricating such memory cells

(76) Inventor: Shoaib Zaidi, Poughkeepsie, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/487,876

(22) Filed: Jul. 17, 2006

(51) Int. Cl. H01L 29/00; H01L 21/8234

(52) U.S. Cl. 257/379; 438/238; 438/382; 257/536

(57) ABSTRACT

A method of fabricating memory cells on a wafer includes forming cavities in a dielectric layer, where each of the cavities includes at least one corner. The method additionally includes depositing a memory cell material into the corner(s) of the cavities, and removing a portion of the memory cell material from the cavities such that an active portion of the memory cell material remains in the corner(s).

### BACKGROUND

Semiconductor chips provide memory storage for electronic devices and have become very popular in the electronic products industry. In general, many semiconductor chips are typically fabricated (or built) on a silicon wafer. The semiconductor chips are individually separated from the wafer for subsequent use as memory in electronic devices. Semiconductor chips include memory cells that store retrievable data, often characterized by the logic values of 0 and 1. Some memory cells are resistive memory cells that permit memory states to be set and retrieved resistively.

Phase change memory cells are one type of resistive memory cell capable of storing retrievable data between two or more separate states (or phases). In one known structure of a phase change memory cell, the memory cell is formed at the intersection of a phase change memory material and an electrode. Delivering an appropriate amount of energy to the electrode heats the phase change memory cell, thus affecting a phase/state change in its atomic structure. The phase change memory cell can be selectively switched between logic states 0 and 1, for example, and/or selectively switched between multiple logic states.

Materials that exhibit the above-noted phase change memory characteristics include the elements of Group VI of the periodic table (such as Tellurium and Selenium) and their alloys, referred to as chalcogenides or chalcogenic materials. Other non-chalcogenide materials also exhibit phase change memory characteristics.

The atomic structure of one type of phase change memory cell can be switched between an amorphous state and one or more crystalline states. The amorphous state has greater electrical resistance than the crystalline state(s), and typically includes a disordered atomic structure. In contrast, the crystalline states each generally have a highly ordered atomic structure, and the more ordered the atomic structure of the crystalline state, the lower the electrical resistance (and the higher the electrical conductivity).

The atomic structure of a phase change material becomes highly ordered when maintained at (or slightly above) the crystallization temperature. A subsequent slow cooling of the material results in a stable orientation of the atomic structure in the highly ordered (crystalline) state. To switch back, or reset, to the amorphous state, for example in the chalcogenide material, the local temperature is generally raised above the melting temperature (approximately 600 degrees Celsius) to achieve a highly random atomic structure, and then rapidly cooled to “lock” the atomic structure in the amorphous state.

The temperature-induced set/rest changes in phase/state may be achieved in a variety of ways. For example, a laser can be directed to the phase change material, current can be driven through the phase change material, or current can be passed through a resistive heater adjacent the phase change material. In any of these methods, controlled heating of a critical dimension (CD) of the phase change material in the memory cell causes controlled phase (i.e., memory state) change, and hence, controlled data storage within the phase change memory cell.

It is desirable to have reproducible and consistent current-induced changes in the memory state of the phase change material. In addition, it is desired to reduce the power needed to change memory states in memory cells to enable the use of smaller selection devices, thus reducing an overall size for memory devices, in general.

For these and other reasons, there is a need for the present invention.

### SUMMARY

One embodiment provides a method of fabricating memory cells on a wafer. The method includes forming cavities in a dielectric layer, where each of the cavities includes at least one corner. The method additionally includes depositing a memory cell material into the corner(s) of the cavities, and removing a portion of the memory cell material from the cavities such that an active portion of the memory cell material remains in the corner(s).

### BRIEF DESCRIPTION OF THE DRAWINGS

The accompanying drawings are included to provide a further understanding of the present invention and are incorporated into and form a part of this specification. The drawings illustrate embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a simplified block diagram of a memory device including memory cells according to one embodiment of the present invention.

FIG. 2 illustrates a cross-sectional view of a pillar memory cell according to one embodiment of the present invention.

FIG. 3 illustrates a top view of a pre-processed wafer including electrode plugs disposed at a pitch in an array according to one embodiment of the present invention.

FIG. 4 illustrates a cross-sectional view of the pre-processed wafer illustrated in FIG. 3 including a dielectric layer according to one embodiment of the present invention.

FIG. 5 illustrates a cross-sectional view of a photoresist imaged and developed onto the dielectric layer illustrated in FIG. 4 according to one embodiment of the present invention.

FIG. 6 illustrates a cross-sectional view of a pattern etched into a dielectric layer according to one embodiment of the present invention.

FIG. 7 illustrates a top view of a pattern etched over a contact-to-array, where the etched pattern is sized on the order of a pitch for the contact-to-array according to one embodiment of the present invention.

FIG. 8 illustrates a cross-sectional view of a layer of a memory cell material deposited into corners and on side walls of a pattern etched in a dielectric according to one embodiment of the present invention.

FIG. 9 illustrates a cross-sectional view of the memory cell material illustrated in FIG. 8 after a shielded etch according to one embodiment of the present invention.

FIG. 10 illustrates a top view of discrete slivers of memory cell material patterned onto electrodes of the pre-processed wafer according to one embodiment of the present invention.

FIG. 11 illustrates a perspective view of a sliver of memory cell material according to one embodiment of the present invention.

FIG. 12A illustrates a cross-sectional view of a dielectric fill deposited over patterned memory cell material according to one embodiment of the present invention.

FIG. 12B illustrates a cross-sectional view of a dielectric fill deposited over patterned memory cell material and planarized according to one embodiment of the present invention.

FIG. 13A illustrates a cross-sectional view of a dielectric fill after top electrode etching according to one embodiment of the present invention.

FIG. 13B illustrates a cross-sectional view of a planarized dielectric fill including a top electrode according to one embodiment of the present invention.

FIG. 14 illustrates a cross-sectional view of a deposition of top electrode material in contact with memory cell material according to one embodiment of the present invention.

FIG. 15 illustrates a cross-sectional view of a mushroom memory cell according to another embodiment of the present invention.

FIG. 16 illustrates a cross-sectional view of a pre-processed wafer including a dielectric layer according to one embodiment of the present invention.

FIG. 17 illustrates a cross-sectional view of a photoresist imaged and developed onto the dielectric layer illustrated in FIG. 16 according to one embodiment of the present invention.

FIG. 18 illustrates a cross-sectional view of a pattern etched into a dielectric layer according to one embodiment of the present invention.

FIG. 19 illustrates a top view of a pattern etched over a contact-to-array, where the etched pattern is sized on the order of a pitch for the contact-to-array according to one embodiment of the present invention.

FIG. 20 illustrates a cross-sectional view of a layer of memory cell material deposited into corners and on side walls of a pattern etched in a dielectric according to one embodiment of the present invention.

FIG. 21 illustrates a cross-sectional view of the memory cell material illustrated in FIG. 20 after a shielded etch according to one embodiment of the present invention.

FIG. 22 illustrates a perspective view of a sliver of memory cell material according to another embodiment of the present invention.

FIG. 23 illustrates a cross-sectional view of a phase change memory material deposited over patterned memory cell material according to one embodiment of the present invention.

FIG. 24 illustrates a cross-sectional view of a deposition of top electrode material in contact with the phase change memory material illustrated in FIG. 23 according to one embodiment of the present invention.

FIG. 25 illustrates a cross-sectional view of an isolated mushroom memory cell according to one embodiment of the present invention.

### DETAILED DESCRIPTION

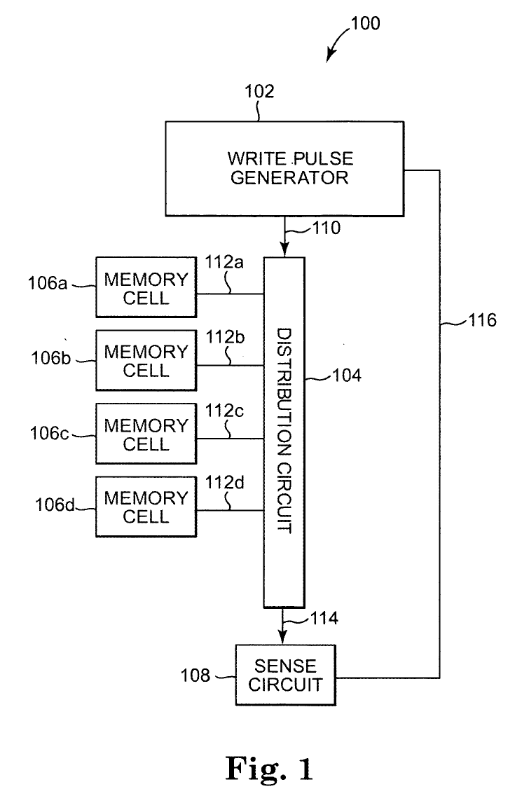

FIG. 1 illustrates a simplified block diagram of a memory device 100 according to one embodiment of the present invention. Memory device 100 includes a write pulse generator 102, a distribution circuit 104, memory cells 106a, 106b, 106c, and 106d, and a sense circuit 108. In one embodiment, memory cells 106a-106d are phase change memory cells that beneficially employ an amorphous to crystalline phase transition of memory material within the cell for storing data in the memory. Write pulse generator 102 is electrically coupled to distribution circuit 104 through signal path 110. Distribution circuit 104 is electrically coupled to memory cells 106a-106d through signal paths 112a-112d, respectively, and to sense circuit 108 through signal path 114. Write pulse generator 102 is electrically coupled to sense circuit 108 through a signal path 116. Each of the memory cells 106a-106d can be programmed into a memory state associated with a particular resistance value, and the resistance value is controlled using a suitable electrical write strategy.

As used herein the term “electrically coupled” is not meant to mean that the elements must be directly coupled together, and intervening elements may be provided between the “electrically coupled” elements.

Some phase change materials exhibit more than one crystalline phase. For example, a low temperature crystalline state may have a lower electrical resistance than the amorphous state, and the high-temperature crystalline state may have an electrical resistance that is lower than both the lower temperature crystalline state and the amorphous state. However, the transition of the phase change material into the higher temperature crystalline state is not generally desirable because a large current is required to switch the phase change material from the high temperature crystalline state back to the amorphous state. In one embodiment, the phase change material is not switchable into the higher temperature crystalline state. However, other embodiments provide for switching the phase change material into the higher temperature crystalline state, for example, by switching the phase change material between the lower and the higher temperature crystalline states, such that the phase change material is selectively controlled to not switch into the amorphous state.

In one embodiment, each phase change memory cell 106a-106d includes phase change material providing a data storage location. The active region for the phase change memory cell is where the phase change material transitions between the crystalline state and the amorphous state for storing one bit, 1.5 bits, two bits, or several bits of data.

In one embodiment, write pulse generator 102 generates current or voltage pulses that are controllably directed to memory cells 106a-106d via distribution circuit 104. In one embodiment, distribution circuit 104 includes a plurality of transistors that controllably direct current, voltage, or power pulses to the memory cells.

In one embodiment, memory cells 106a-106d include a phase change material that can be changed from an amorphous state to a crystalline state, or from a crystalline state to an amorphous state, under influence of a temperature change. These crystalline memory states are useful for storing data in memory device 100. The memory state(s) can be assigned to the bit values, such as bit values “0” and “1.” The bit states of memory cells 106a-106d differ significantly in their electrical resistivity. In the amorphous state, a phase change material exhibits significantly higher resistivity than in the crystalline state. In this manner, sense amplifier 108 reads the cell resistance such that the bit value assigned to a particular memory cell 106a-106d is determined.

To program one of the memory cells 106a-106d within memory device 100, write pulse generator 102 generates a current or voltage pulse for heating the phase change material in the target memory cell. In one embodiment, write pulse generator 102 generates an appropriate current or voltage pulse, which is fed into distribution circuit 104 and distributed to the appropriate target memory cell 106a-106d. The current or voltage pulse amplitude and duration is controlled depending on whether the memory cell is being set or reset. Generally, a “set” operation of a memory cell heats the phase change material of the target memory cell above its crystallization temperature (but below its melting temperature) long enough to achieve the crystalline state. Generally, a “reset” operation of a memory cell heats the phase change material of the target memory cell above its melting temperature, and then quickly quenches/cools the material, thereby achieving the amorphous state.

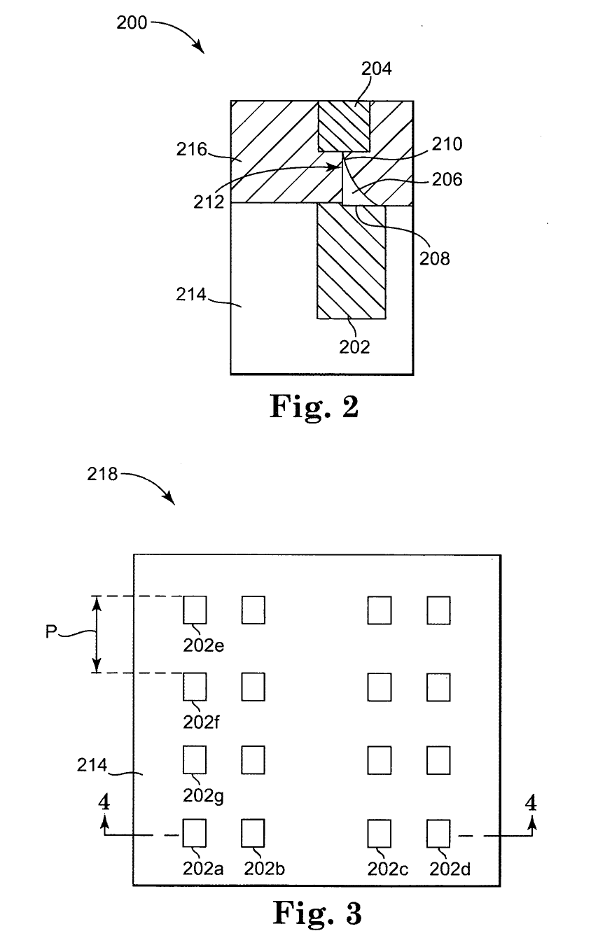

FIGS. 2-15 illustrate various embodiments of a memory cell including a small critical dimension (CD) at the top electrical contact region. In one embodiment, this sub-lithographic sized contact is achieved by utilizing photolithography, etching, deposition, a second etch, dielectric deposition and planarization. The lithography requirements are very relaxed when compared with the state of the art. The dimensions of lithography are approximately equal to the pitch (spatial periodicity) of the structures. Such lithography can be performed at much lower cost than more aggressive (smaller feature) lithography.

FIG. 2 illustrates a cross-sectional view of a pillar memory cell 200 according to one embodiment of the present invention. Memory cell 200 includes a first electrode 202 and an opposing second electrode 204, and a volume 206 of phase change material extending between first electrode 202 and second electrode 204. Volume 206 of phase change material tapers in width from a base 208 contacting first electrode 202 to an apex 210 contacting second electrode 204. In one embodiment, volume 206 of phase change material defines a tetrahedron, and apex 210 can be selectively patterned and or processed (for example by polishing) to terminate at an active region 212 having a desired sub-lithographically small lateral dimension. In general, memory cell 200 is one memory cell in an array of memory cells, and dielectric 214 insulates electrode 202 from other electrodes, and dielectric 216 insulates active region 212 and second electrode 204 from other active regions and electrodes of other cells in the array.

Selective patterning and/or termination of apex 210 defines a critical dimension (CD) of volume 206 of phase change material. In one embodiment, the CD is fabricated to define a sub-lithographic dimension of less than about 90 nanometers (nm), and preferably the CD is fabricated to define a sub-lithographic dimension of between about 1-65 nm. In this regard, active region 212 includes a dimension on the order of the CD, such that the CD enables low power changes between memory states in memory cell 200.

FIG. 3 illustrates a top view of a pre-processed wafer 218 according to one embodiment of the present invention. Pre-processed wafer 218 includes electrode plugs 202 disposed in a field 214 of dielectric material. In this regard, electrodes 202 provide contact to other portions of the array such that pre-processed wafer 218 is also referred to as a contact-to-array (CA). Electrodes 202 are disposed in an array. For example, electrodes 202a, 202b, 202c, and 202d are disposed across columns of the array, and electrodes 202e, 202f, and 202g are disposed across rows of the array. A pitch P is defined, for example, as a distance between rows of electrodes in the array. For example, the distance between electrode 202e and electrode 202f defines a pitch dimension P. In one embodiment, electrodes 202 include a TiN plug, a tungsten plug, a copper plug, a tantalum nitride (TaN) plug, or a plug of other suitable electrode material.

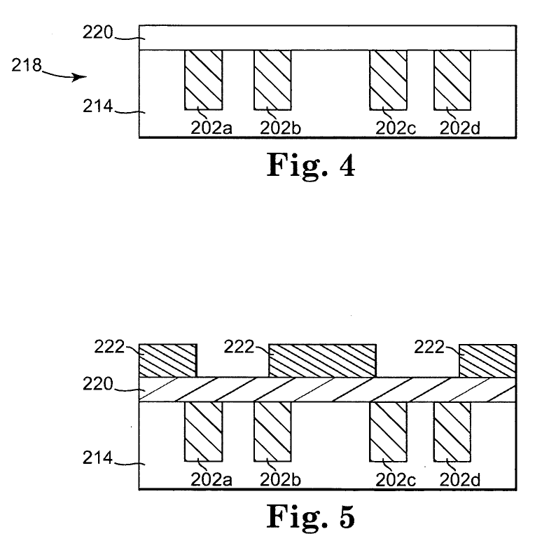

FIG. 4 illustrates a cross-sectional view of pre-processed wafer 218 including layer 220 of dielectric material according to one embodiment of the present invention. Layer 220 is, in general, an insulating field and can include an oxide field, a nitride field, or other low-k dielectric materials having suitable thermal etch and electrical characteristics. In one embodiment, layer 220 is an insulator and includes silicon dioxide, fluorinated silica glass (FSG), or other suitable dielectric materials.

FIG. 5 illustrates a cross-sectional view of a photoresist 222 that has been imaged and developed onto dielectric layer 220 according to one embodiment of the present invention. In one embodiment, photoresist 222 is a positive photoresist that is masked/patterned to align approximately over a central portion of electrodes 202a, 202b, 202c, and 202d, as illustrated. In another embodiment, photoresist 222 is a negative photoresist that is masked/patterned to align approximately over a central portion of electrodes 202a, 202b, 202c, and 202d, as illustrated. In one embodiment, photoresist 222 is deposited/patterned onto layer 220 by spin coating a thin and uniform layer of photoresist 222 onto layer 220, masked, and imaged and developed in a suitable photolithographic process.

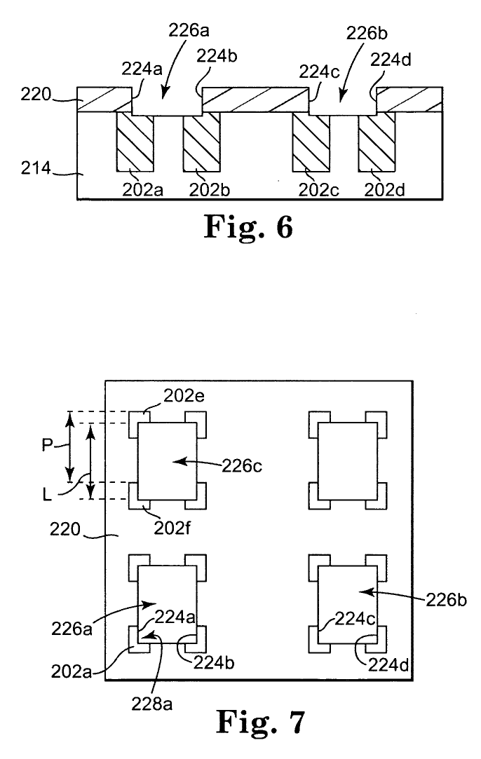

FIG. 6 illustrates a cross-sectional view of dielectric layer 220 after photolithographic exposure, develop and etch processes according to one embodiment of the present invention. Layer 220 has been etched to define sidewalls 224a, 224b, 224c, and 224d aligned with electrodes 202a, 202b, 202c, and 202d, respectively. In one embodiment, the etch includes a halogen-chemistry etch having a suitable etch rate relative to dielectric layer 220. In one embodiment, sidewalls 224 are substantially vertical relative to electrodes 202. In another embodiment, one or more sidewalls 224 are undercut and disposed at an angle relative to a planar top surface of electrodes 202. In this manner, a cavity 226a is formed extending between electrodes 202a and 202b, and a cavity 226b is formed and extends between electrodes 202c and 202d.

FIG. 7 illustrates a top view of etched dielectric layer 220 according to one embodiment of the present invention. Cavities 226a, 226b, and 226c have been formed in layer 220 of dielectric material such that corners of cavities 226 overlap a central portion of electrodes 202. For example, corner 228a overlaps and is substantially centrally located over electrode 202a.

In one embodiment, cavities 226 are photo-lithographically patterned and have a length L that is on the order of a pitch dimension P for the array of electrodes 202. Bulk formation of cavities 226 photo-lithographically over electrodes 202 where the length of the cavity L is on the order of the pitch P is relatively inexpensive, and can be produced quickly and efficiently. In this manner, cavities 226 are block patterned and aligned relative to electrodes 202 and suited for subsequent processing, such as the deposition of thin film materials. As described below, this block patterning of cavities 226 over electrodes 202 is combined with thin film deposition of memory cell material such that highly uniform and small CD dimensions of memory cells can be patterned above electrodes 202.

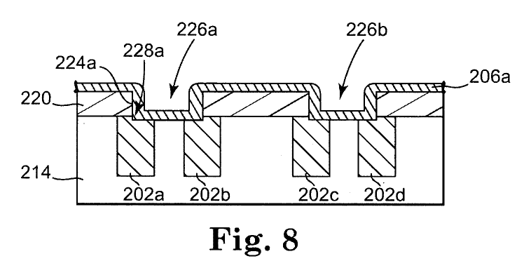

FIG. 8 illustrates a cross-sectional view of a layer 206a of memory cell material deposited into cavities 226a and 226b according to one embodiment of the present invention. In one embodiment, layer 206a of memory cell material is conformally deposited into cavities 226a, 226b such that memory cell material uniformly coats corners, for example corner 228a, of cavity 226a.

In one embodiment, layer 206a of memory cell material is a phase change material including chalcogenide alloys having one or more elements from Group VI of the periodic table, such as Tellurium and/or Selenium and/or Sulfur, and their alloys. In another embodiment, layer 206a of memory cell material is chalcogen-free, i.e., a material that does not contain Tellurium, Selenium, or Sulfur, or alloys of Tellurium, Selenium, or Sulfinur. Suitable materials for layer 206a of memory cell material include, for example, GeSbTe, SbTe, GeTe, AgInSbTe, GeSb, GaSb, InSb, GeGaInSb. In other embodiments, layer 206a includes a suitable material including one or more of the elements Ge, Sb, Te, Ga, As, In, Se, and S. In addition, layer 206a of memory cell material may be selectively doped with nitrogen, oxygen, silicon, or other suitable materials. Layer 206a of memory cell material is deposited using chemical vapor deposition (CVD), atomic layer deposition (ALD), metal organic chemical vapor deposition (MOCVD), plasma vapor deposition (PVD), jet vapor deposition (JVD), or other suitable depositions techniques. In another embodiment, layer 206a of memory cell material is an electrode material, or other suitable component of a memory cell conformally deposited into corners and on side walls of cavities 226.

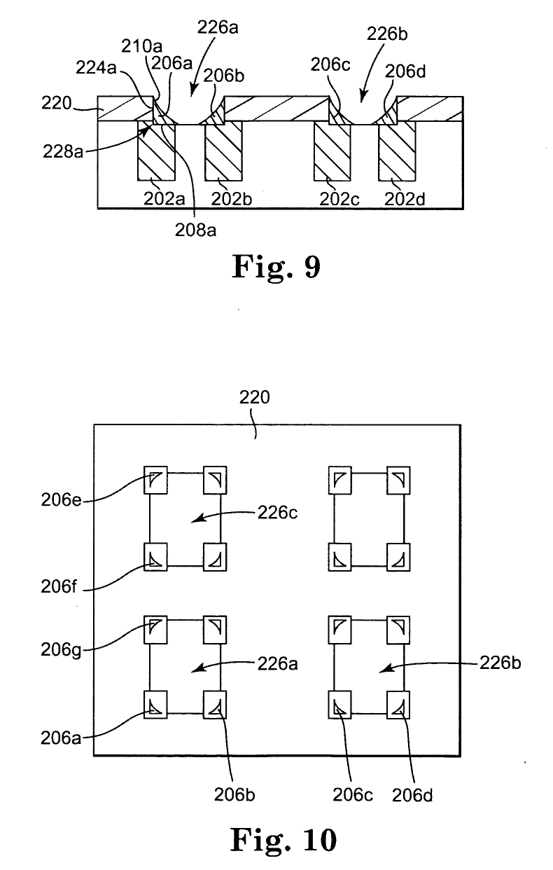

FIG. 9 illustrates a cross-sectional view of memory cell material 206 after a spacer or spacer-like etch according to one embodiment of the present invention. In one embodiment, memory cell material 206 is etched and removed preferentially from horizontal surfaces of dielectric layer 220 and dielectric field 214 such that a sliver of memory cell material 206 remains in corners of layer 220. For example, corner 228a including sidewall 224a is coated with a sliver of memory cell material 206a after the spacer or spacer-like etch. In one embodiment, volume 206a of memory cell material tapers in width from base 208a to apex 210a and contacts sidewall 224a and fills corner 228a. In one embodiment, the spacer or spacer-like etch includes an anisotropic etch that selectively removes a portion of memory cell material 206. In one embodiment, the spacer or spacer-like is a top down style of etch that etches into memory cell material 206, the amount of the etching is controlled by controlling the etchant chemistry and the duration of etching.

In one embodiment, volume 206a includes a phase change material that is shielded by corner 228a and vertical sidewall 224a from the full effects of the etch chemistry and/or process. In one embodiment, volume 206a includes a phase change material that is partially shielded by corner 228a and vertical sidewall 224a from the full effects of the etch chemistry and/or process. In one embodiment, the etch is selected to be a “rounded corner” etch of a suitable etch rate and chemistry such that volume 206a of memory cell material remains in corners of cavities 226. In this manner, a volume 206a of phase change material remains in corners, for example corner 228a, of cavities 226. After spacer etching, volume 206a of phase change material remains and extends in a tapered configuration from a generally wider base 208a in contact with electrode 202a to a generally narrower apex 210a. In one embodiment, the spacer or spacer-like etch is selected to etch selected exposed portions of memory cell material 206 such that unexposed portions of memory cell material 206 remain in corners, for example corner 228a. In one embodiment, a sliver of memory cell material 206 remains in each corner of cavities 226a, 226b.

FIG. 10 illustrates a top view of dielectric layer 220 after spacer etching/fabrication of volumes 206 of memory cell material according to one embodiment of the present invention. In one embodiment, volume 206a is tetrahedron-shaped. Each volume 206 of memory cell material includes at least one sub-lithographic dimension after spacer or spacer-like etch of layer 206 of memory cell material. In this manner, consistently small and uniform critical dimension features are formed in a big block lithographic fabrication process.

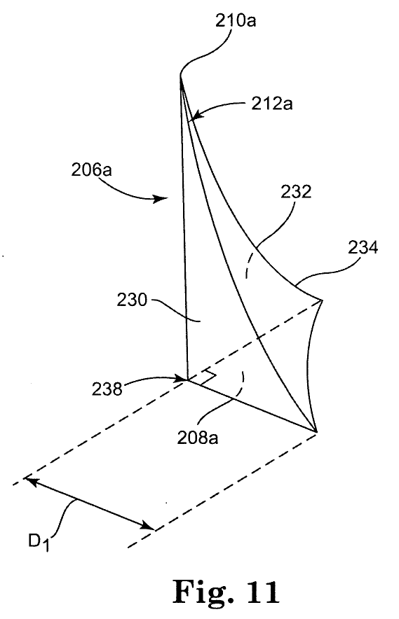

FIG. 11 illustrates a perspective view of volume 206a of memory cell material according to one embodiment of the present invention. In one embodiment, volume 206a defines a substantially tetrahedron-shaped volume of material including a first sidewall 230, and second sidewall 232 substantially orthogonal to first sidewall 230, and a face 234 contacting edges of first and second sidewalls 230, 232 that extends from a substantially triangular base 208a to apex 210a. In one embodiment, sidewall 232 corresponds with and contacts sidewall 224a (FIG. 9) formed in layer 220. In a similar manner, corner 238 corresponds with corner 228a of cavity 226a fabricated in layer 220 (FIG. 9). In one embodiment, base 208a defines a lateral dimension D1 that is selectively scaled to be sub-lithographic in size. For example, in one embodiment, volume 206a is thin film deposited by an ALD process such that lateral dimension D1 is less than 90 nm, and preferably the lateral dimension D1 is between about 1-65 nm, although it is to be understood that such thin film process can deposit materials having a desired lateral dimension on the order of the size of an atom.

In one embodiment, corner 238 is angled relative to sidewall 230 at an angle of other than 90 degrees. In one embodiment, corner 238 is substantially orthogonal and defines a right corner where sidewall 230 is disposed at approximately 90 degrees to sidewall 232. Face 234 is patterned by the spacer or spacer-like etch described above and tapers between base 208a and apex 210a. In one embodiment, a selective polishing of apex 210a removes material and selectively defines an exposed area of the active region 212a, where the exposed area is suitable for contact with a top electrode, for example. In this manner, active region 212a is selectively fabricated to include an area having a desired lateral dimension, for example, a desired sub-lithographic lateral dimension.

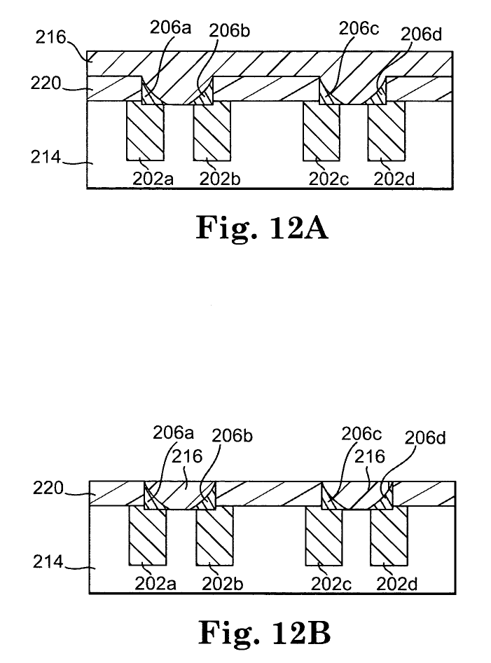

FIG. 12A illustrates a cross-sectional view of a layer 216 of dielectric fill deposited between volumes 206 of memory cell material according to one embodiment of the present invention. Layer 216 of dielectric fill is, in general, an insulating field of silicon dioxide, or other suitable dielectric material having suitable thermal etch and electro characteristics. In one embodiment, layer 216 is an insulator and includes one of silicon dioxide, FSG, or other suitable low-k dielectric materials is deposited using CVD, ALD, MOCVD, PVD, JVD, or other suitable depositions techniques referenced above. In one embodiment, layer 216 is planarized by a suitable planarization process, such as chemical mechanical polishing (CMP), or other planarization processes, as described below.

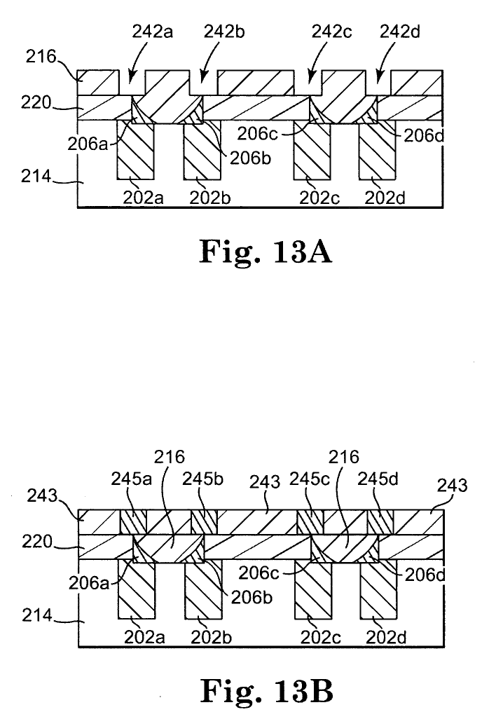

FIG. 12B illustrates a cross-sectional view of a dielectric fill 216 deposited over patterned memory cell material and planarized according to one embodiment of the present invention. Layer 216 of dielectric fill is described above. In one embodiment, layer 216 is planarized to expose, or “open,” a top portion of volumes 206a, 206b, 206c, and 206d respectively, of memory cell material. In one embodiment, layer 216 is chemical mechanical polished (CMP), although other planarization processes are also acceptable. A subsequent electrode deposition process places a suitable top electrode in electrical contact with each open area of the volumes 206a, 206b, 206c, and 206d respectively, of memory cell material, as best illustrated in FIG. 13B.

FIG. 13A illustrates a cross-sectional view of layer 216 of dielectric after patterning for subsequent top electrode fabrication according to one embodiment of the present invention. In one embodiment, layer 216 of dielectric is patterned in a photo-lithographic mask and etch process, similar to FIG. 5 above, to define cavities 242a, 242b, 242c, and 242d that are aligned with volumes 206a, 206b, 206c, and 206d respectively, of memory cell material.

FIG. 13B illustrates a cross-sectional view of a planarized dielectric fill including a top electrode according to one embodiment of the present invention. In one embodiment, layer 216 of dielectric is planarized (FIG. 12B), for example by a CMP process, and a dielectric field 243 is patterned with electrodes 245a, 245b, 245c, and 245d that electrically contact volumes 206a, 206b, 206c, and 206d respectively, of memory cell material.

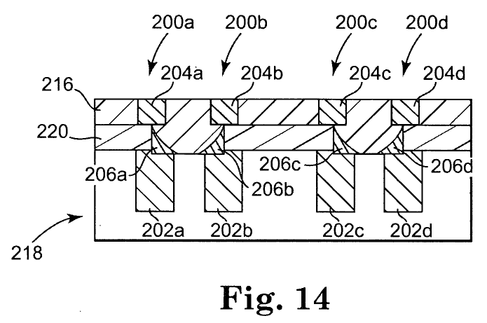

FIG. 14 illustrates a cross-sectional view of pre-processed wafer 218 including a plurality of memory cells 200 according to one embodiment of the present invention. Electrode material 204 has been deposited in contact with volume 206a of memory cell material. In one embodiment, electrode material 204 defines an upper, or second, electrode opposite first electrodes 202 and includes TiN, tungsten, copper, TaN, or other suitable electrode material. Electrodes 204 are deposited using CVD, ALD, MOCVD, PVD, JVD, or other suitable depositions techniques referenced above.

Volume 206 of phase change material extends between first electrode 202 and second electrode 204 to define memory cell 200a. In one embodiment, the array of memory cells illustrated in FIG. 14 is further processed to include other backend electrical components electrically connecting memory cells 200a-200d. In one embodiment, dielectric layer 216 and dielectric layer 220 are similar dielectric materials and define a homogenous field of dielectric insulating and surrounding respective ones of memory cells 200a-200d.

With reference to FIG. 2, one memory cell 200 in an array of such memory cells has been fabricated to include an active region 212 that defines a sub-lithographic dimension of less than about 90 nm, preferably the sub-lithographic dimension is between about 1-65 nm. In one embodiment, volume 206 of memory cell material defines a tetrahedron including a generally triangular shape at base 208 and an apex at 210, where volume 206 of memory cell material defines a small CD active region 212 useful in memory cells with a low RESET current.

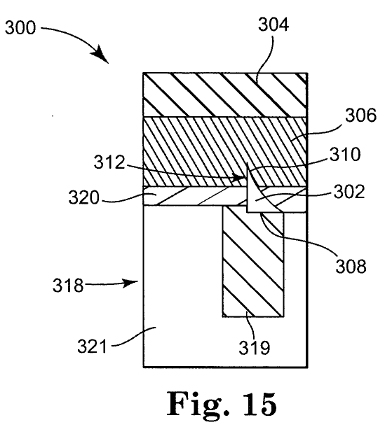

FIGS. 15-25 illustrate various embodiments of a mushroom memory cell including a small critical dimension (CD) at the bottom electrode region. In one embodiment, this sub-lithographic sized contact is achieved by utilizing photolithography, etching, deposition, a second etch, dielectric deposition and planarization. The lithography requirements are relaxed as compared to the state of the art, as noted above. The dimensions of lithography are approximately equal to the pitch (spatial periodicity) of the structures. Such lithography can be performed at much lower cost than more aggressive (smaller feature) lithography. Fabrication of the small and consistent CD enables the use of reduced power in changing memory states in the memory cell, thus enabling the use of smaller selection devices, and reducing an overall size of the memory device.

FIG. 15 illustrates a cross-sectional view of a mushroom memory cell 300 according to one embodiment of the present invention. Memory cell 300 includes a sub-lithographically patterned bottom electrode 302, an opposing second electrode 304, and a volume 306 of phase change material extending between first electrode 302 and second electrode 304. In one embodiment, patterned electrode 302 is patterned in a dielectric layer 320 that is otherwise deposited on a pre-processed wafer 318 substantially similar to pre-processed wafer 218 of FIG. 3 above. In this regard, pre-processed wafer 318 includes an array of electrode plugs 319 disposed in a dielectric field 321. In general, memory cell 300 is one memory cell in an array of memory cells, and dielectric 321 insulates electrode 319 from other electrodes in the array. Although not illustrated, it is to be understood that memory cell 300 is electrically isolated from other cells, such that volume 306 of phase change material of one cell is isolated from other volumes of phase change material, for example, by an isolation etch.

In one embodiment, patterned bottom electrode 302 is tapered in width from a base 308 contacting electrode 319 to an apex 310 contacting phase change material 306. In one embodiment, patterned bottom electrode 302 defines a tetrahedron, and apex 310 can be selectively patterned and or processed (for example by polishing) to terminate at an active region 312 having a desired lateral dimension.

Selective patterning and/or termination of apex 310 defines a critical dimension in active region 312 of patterned bottom electrode 302. In one embodiment, the CD is fabricated to define a sub-lithographic dimension of less than about 90 nanometers (nm), and preferably the CD is fabricated to define a sub-lithographic dimension of between about 1-65 nm. In this regard, active region 312 includes a dimension on the order of the CD, and the CD is consistently patterned to be small and enable low power changes to the memory states in memory cell 300.

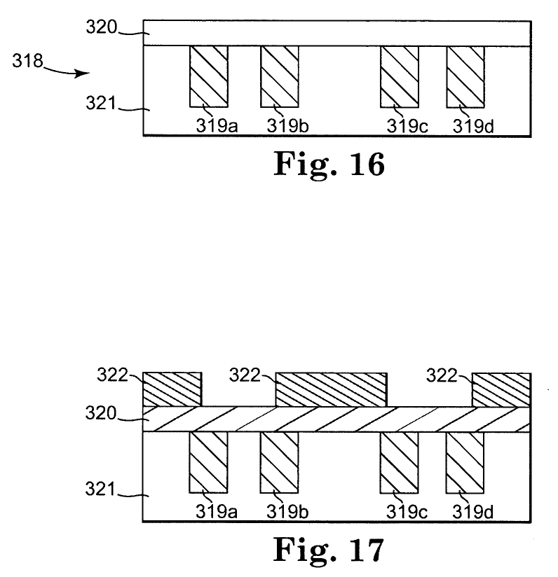

FIG. 16 illustrates a cross-sectional view of pre-processed wafer 318 including layer 320 of dielectric material according to one embodiment of the present invention. Layer 320 is, in general, an insulating field and can include an oxide field, a nitride field, or other low-k dielectric materials having suitable thermal etch and electrical characteristics. In one embodiment, layer 320 is an insulator and includes silicon dioxide, fluorinated silica glass (FSG), or other suitable dielectric materials.

FIG. 17 illustrates a cross-sectional view of a photoresist 322 patterned onto dielectric layer 320 according to one embodiment of the present invention. In one embodiment, photoresist 322 is a positive photoresist that is patterned to align approximately over a central portion of electrodes 319a, 319b, 319c, and 319d. In another embodiment, photoresist 322 is a negative photoresist that is masked and patterned to align approximately over a central portion of electrodes 319a, 319b, 319c, and 319d, as illustrated. In one embodiment, photoresist 322 is deposited and patterned onto layer 320 by spin coating a thin and uniform layer of photoresist mask 322 onto layer 320, masking the photoresist 322, and imaging and developing the photoresist 322 in a suitable photolithographic process.

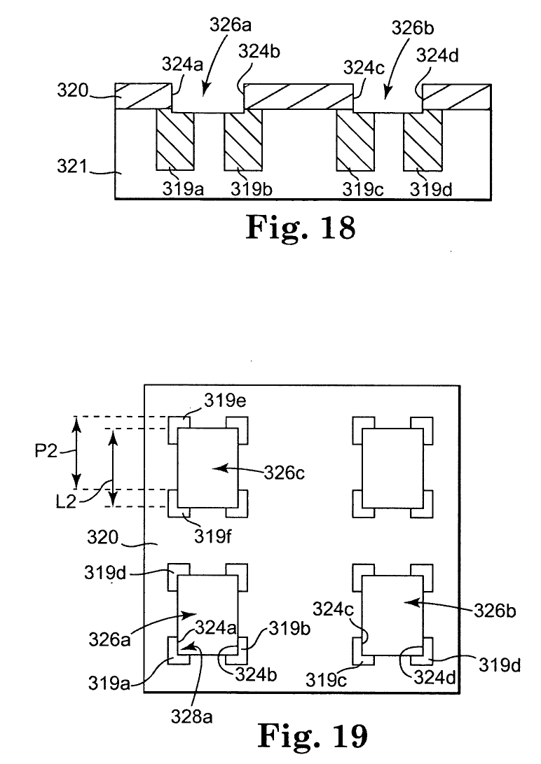

FIG. 18 illustrates a cross-sectional view of dielectric layer 320 after photolithographic exposure, develop and wash processes according to one embodiment of the present invention. Layer 320 has been etched to define sidewalls 324a, 324b, 324c, and 324d aligned with electrodes 319a, 319b, 319c, and 319d, respectively. In one embodiment, sidewalls 324 are substantially vertical relative to electrodes 319. In another embodiment, one or more sidewalls 324 are undercut and disposed at an angle relative to a planar top surface of electrodes 319. In this manner, a cavity 326a is formed extending between electrodes 319a and 319b, and a cavity 226b is formed and extends between electrodes 319c and 319d.

FIG. 19 illustrates a top view of etched dielectric layer 320 according to one embodiment of the present invention. Cavities 326a, 326b, and 326c have been formed in layer 320 of dielectric material such that corners of cavities 326 overlap a central portion of electrodes 319. For example, corner 328a overlaps and is substantially centrally located over electrode 319a.

In one embodiment, cavities 326 are photo-lithographically patterned and have a length L2 that is on the order of a pitch dimension P2 for the array of electrodes 319, in a manner similar to FIG. 7 above. Forming cavities 326 photo-lithographically over electrodes 319 where the length of the cavity L2 is on the order of the pitch P2 is relatively inexpensive, and can be produced quickly and efficiently. In this manner, cavities 326 are patterned in a block and aligned relative to electrodes 319 and suited for subsequent processing, such as the deposition of thin film materials. As described below, this block patterning of cavities 326 over electrodes 319 is combined with thin film deposition of materials, such as bottom electrode material, enables highly uniform and small CD dimensions of memory cells can be patterned above electrodes 319 by bulk processes, such as photolithography.

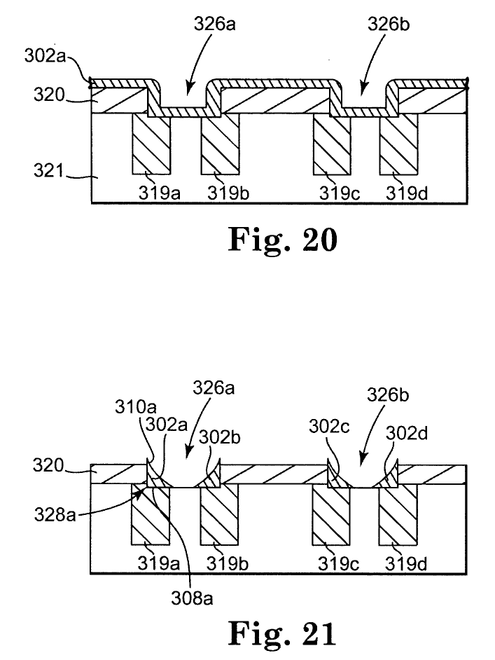

FIG. 20 illustrates a cross-sectional view of a layer 302a of electrode material deposited into cavities 326a and 326a according to one embodiment of the present invention. In one embodiment, layer 302a of electrode material is bottom electrode material that is conformally deposited into cavities 326a and 326a such that the electrode material uniformly coats corners, for example corner 328a, of cavity 326a.

In one embodiment, layer 302a of electrode material is suitable for use as a bottom electrode of a memory cell. In one embodiment, layer 302a of electrode material includes TiN, tungsten, copper, tantalum nitride, or other suitable electrode material. Layer 302a of electrode material is deposited using CVD, ALD, MOCVD, PVD, JVD, or other suitable depositions techniques referenced above.

FIG. 21 illustrates a cross-sectional view of electrode material 302 after a spacer or spacer-like etch according to one embodiment of the present invention. In one embodiment, electrode material 302 is etched and removed from horizontal surfaces of dielectric layer 320 such that a sliver of electrode material 302 remains in corners of layer 320. For example, corner 328a including sidewall 324a is coated with a sliver of electrode material 302a after the spacer or spacer-like etch. In one embodiment, volume 302a of electrode material tapers in width from base 308a to apex 310a and contacts sidewall 324a and fills corner 328a.

In one embodiment, volume 302a includes a bottom electrode material that is shielded by corner 328a and vertical sidewall 324a from the full effects of the etch chemistry and/or process. In this manner, a volume 302a of phase change material remains in corners, for example corner 328a, of cavities 326. After spacer etching, volume 302a of bottom electrode material remains and extends in a tapered configuration from a generally wider base 308a in contact with electrode 319a to a generally narrower apex 310a. In one embodiment, apex 310a extends beyond layer 320 to provide contact with a subsequent layer deposited over volumes 302a-302d of electrode material. In one embodiment, the spacer etch etches selected exposed portions of electrode material 302 such that unexposed portions of electrode material 302 remain in corners, for example corner 328a. In one embodiment, a sliver of electrode material 302 remains in each corner of cavities 326a, 326b.

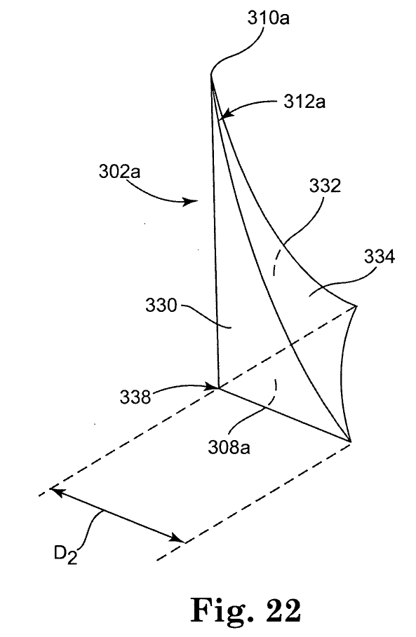

FIG. 22 illustrates a perspective view of volume 302a of electrode material according to one embodiment of the present invention. In one embodiment, volume 302a defines a substantially tetrahedron-shaped volume of bottom electrode material including a first sidewall 330, and second sidewall 332 substantially orthogonal to first sidewall 330, and a face 334 contacting edges of first and second sidewalls 330, 332 that extends from a substantially triangular base 308a to apex 310a. In one embodiment, sidewall 332 corresponds with and contacts sidewall 324a (FIG. 18) formed in layer 320. In a similar manner, corner 338 corresponds with corner 328a of cavity 326a fabricated in layer 320 (FIG. 21). In one embodiment, base 308a defines a lateral dimension D2 that is selectively scaled to be sub-lithographic in size. For example, in one embodiment, volume 302a is thin film deposited by an ALD process such that lateral dimension D2 is less than 90 nm, and preferably the lateral dimension D2 is between about 1-65 nm, although it is to be understood that such thin film process can deposit materials having a desired lateral dimension on the order of the size of an atom (i.e., much smaller than sub-lithographic in dimension).

In one embodiment, corner 338 is angled relative to sidewall 330 at an angle of other than 90 degrees. In one embodiment, corner 338 is substantially orthogonal and defines a right corner where sidewall 330 is disposed at approximately 90 degrees to sidewall 332. Face 334 is patterned by the spacer or spacer-like etch described above and tapers between base 308a and apex 310a. In one embodiment, a selective polishing of apex 310a removes material and selectively defines an exposed area of the active region 312a, where the exposed area is suitable for contact with a phase change material in a mushroom cell, for example. In this manner, active region 312a is selectively fabricated to include an area having a desired lateral dimension, for example, a desired sub-lithographic lateral dimension.

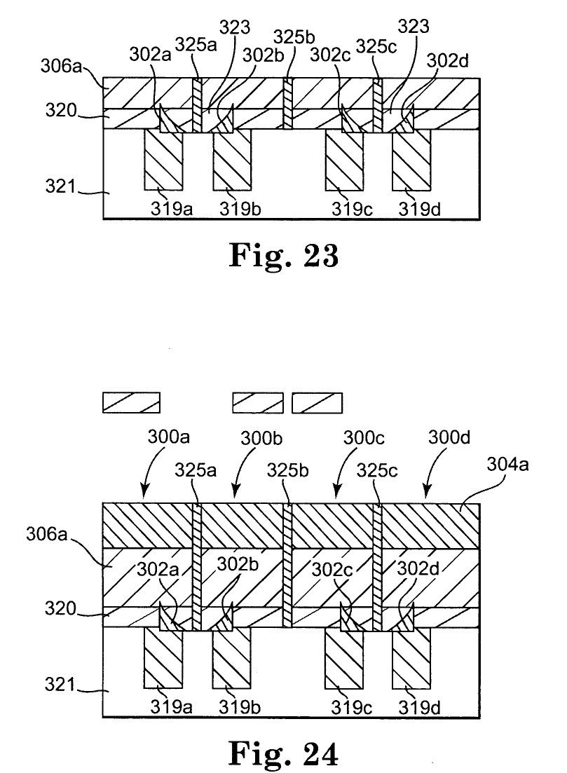

FIG. 23 illustrates a cross-sectional view of a layer 306a of phase change material deposited in contact with volumes 302a-302d of electrode material according to one embodiment of the present invention. In one embodiment, layer 306a of phase change material includes chalcogenide alloys having one or more elements from Group VI of the periodic table, such as Tellurium and/or Selenium and/or Sulfur, and their alloys. In another embodiment, 306a of phase change material is chalcogen-free, i.e., a material that does not contain Tellurium, Selenium, or Sulfur, or alloys of Tellurium, Selenium, or Sulfur. Suitable materials for layer 306a of phase change material include, for example, GeSbTe, SbTe, GeTe, AgInSbTe, GeSb, GaSb, InSb, GeGaInSb. In other embodiments, layer 306a includes a suitable material including one or more of the elements Ge, Sb, Te, Ga, As, In, Se, and S. In addition, layer 306a of phase change material may be selectively doped with nitrogen, oxygen, silicon, or other suitable materials.

In one embodiment, volumes 302a-302d of memory cell material (See FIG. 21) are separated by a dielectric layer 323, and layers 320 and 323 of dielectric material are planarized (for example, CMP planarized). Layer 306a of phase change material is deposited onto the planarized surfaces of layers 320 and 323 of dielectric material. Layer 306a of memory cell material is deposited using chemical vapor deposition, atomic layer deposition, metal organic chemical vapor deposition, plasma vapor deposition, jet vapor deposition, or other suitable depositions techniques, and preferably is conformally deposited into corners and on side walls of cavities 326. Thereafter, a separation etch and fill, illustrated at 325a, 325b, 325c, electrically separates the respective volumes 302a-302d of memory cell material.

FIG. 24 illustrates a cross-sectional view of a layer 304a of electrode material deposited over the phase change material illustrated in FIG. 22. In one embodiment, layer 304a of electrode material is selected to be top electrode material suitable for use in a mushroom memory cell, and appropriately isolated with an isolation etch/fill 325a, 325b, 325c. In one embodiment, layer 304a of electrode material includes TiN, tungsten, copper, tantalum nitride, or other suitable electrode material. Layer 304a of memory cell material is deposited employing suitable thin film depositions referenced above, such as CVD, ALD, MOCVD, PVD, JVD, or other suitable thin film depositions techniques.

In one embodiment, electrically isolated mushroom memory cells 300a, 300b, 300c, and 300d are fabricated onto a pre-processed wafer 318 (FIG. 16) and subsequently electrically separated, for example by an anisotropic separation etch that is later filled with an insulating material, such as, for example, silicon dioxide, although other suitable insulation materials are also acceptable.

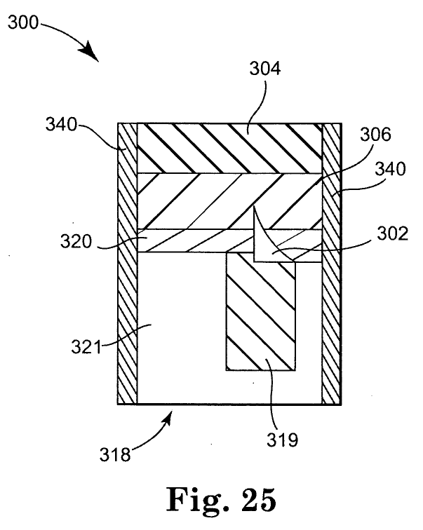

FIG. 25 illustrates a cross-sectional view of a mushroom memory cell 300 electrically separated from other memory cells according to one embodiment of the present invention. In one embodiment, memory cell 300 includes lateral insulation 340 that electrically separates memory cell 300 from other memory cells in an array. Memory cell 300 includes a sub-lithographically patterned bottom electrode 302, an opposing second electrode 304, and a volume 306 of phase change material extending between first electrode 302 and second electrode 304.

Memory cells including small (i.e., sub-lithographic sized) CD advantageously fabricated on a relatively large scale, for example by photolithography, have been described. In one embodiment, the small CD of the memory cells is thin film deposited on a “big block” scale to achieve a small feature size. Such fabrication can be done without trimming the CD/active region, which saves time and is cost-efficient. The small and consistent CD of the memory cells enables the use of reduced power in changing memory states in the memory cells, thus enabling the use of smaller selection devices, and reducing an overall size of the memory device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of fabricating memory cells on a wafer, the method comprising:
forming cavities in a dielectric layer, each of the cavities including at least one corner;
depositing a memory cell material into the at least one corner of the cavities; and
removing a portion of the memory cell material from the cavities such that an active portion of the memory cell material remains in the at least one corner.

2. The method of claim 1, wherein a lateral dimension of the active portion of the memory cell material is less than 65 nm.

3. The method of claim 1, wherein forming cavities in a dielectric layer comprises etching a dielectric layer of a pre-processed wafer to define a first sidewall and a second sidewall that intersect at a corner, the first sidewall substantially orthogonal to the second sidewall.

4. The method of claim 1, wherein the memory cell material is one of a metal electrode material and a phase change material.

5. The method of claim 4, wherein the memory cell material is a metal electrode material and the active portion is a bottom electrode contact.

6. The method of claim 4, wherein the memory cell material is a phase change material and the active portion extends between an opposing pair of electrodes in a memory cell of a pre-processed wafer.

7. The method of claim 1, wherein removing a portion of the memory cell material comprises removing all but the memory cell material in the at least one corner by etching the memory cell material and partially shielding an active portion of the memory cell material with the at least one corner.

8. A memory cell comprising:
a first electrode and an opposing second electrode; and
a volume of phase change material extending between the first and second electrodes, the volume of phase change material tapering in width from a base contacting the first electrode to an apex contacting the second electrode;
wherein the base defines a substantially triangular area in contact with the first electrode.

9. The memory cell of claim 8, wherein the apex contacting the second electrode defines an active region of the phase change material, the active region having a lateral dimension of between 1-90 nm.

10. The memory cell of claim 8, wherein the volume of phase change material defines a tetrahedron, the tetrahedron comprising:
a first sidewall;
a second sidewall substantially orthogonal to the first sidewall; and
a face contacting edges of the first and second sidewalls and extending from the substantially triangular base to the apex.

11. The memory cell of claim 10, wherein the base is wider than the apex, and the sidewalls and the face each taper in width between the base and the apex.

12. The memory cell of claim 8, wherein the volume of phase change material comprises one of a chalcogen and a chalcogen-free phase change material.

13. A method of fabricating memory cells on a pre-processed wafer, the method comprising:
depositing a dielectric layer over electrode plugs of a pre-processed wafer;
etching through the dielectric layer to define cavities in the dielectric layer that expose a portion of the electrode plugs, the cavities including corners;
depositing a phase change material into the corners of the cavities; and
etching the phase change material to define a volume of phase change material in the corners extending from a base contacting a respective one of the electrode plugs to an apex substantially co-planar with a top surface of the dielectric layer.

14. The method of claim 13, wherein depositing a phase change material into the corners of the cavities comprises conformally depositing a phase change material into the corners.

15. The method of claim 14, wherein etching the phase change material comprises etching and removing the phase change material in the cavity and shielding the conformal deposition of phase change material in the corners from etching.

16. The method of claim 13, further comprising:
forming a top electrode in contact with the apex and opposite one of the electrode plugs.

17. A memory device comprising:
a distribution circuit;
a write pulse generator electrically coupled to the distribution circuit;
a sense circuit electrically coupled to the distribution circuit and electrically coupled to the write pulse generator through a signal path; and
an array of memory cells electrically coupled to the distribution circuit, each memory cell comprising:
a volume of phase change material extending between a first electrode and a second electrode, the volume of phase change material tapering from a base contacting the first electrode to an apex defining an active region of the memory cell contacting the second electrode;
wherein a lateral dimension of the apex is between 1-90 nm.

18. The memory device of claim 17, wherein the volume of phase change material defines a tetrahedron, the base of the tetrahedron being wider than the apex.

19. The memory device of claim 17, wherein the phase change material is one of a chalcogen and a chalcogen-free phase change material.

20. The memory device of claim 17, wherein the lateral dimension of the apex is less than 65 nm.

21. A method of patterning multiple memory cells comprising:
depositing a dielectric layer over multiple first electrodes;
forming cavities in the dielectric layer, each of the cavities communicating with at least one of the first electrodes and including at least one corner;
depositing a phase change material into the at least one corner of each of the cavities; and
removing a portion of the phase change material from each of the cavities such that the phase change material in the at least one corner remains.

22. The method of claim 21, wherein forming cavities in the dielectric layer comprises etching the dielectric layer to define a substantially vertical sidewall on either side of the at least one corner.

23. The method of claim 21, wherein forming cavities in the dielectric layer comprises forming cavities that communicate with a plurality of the first electrodes.

24. The method of claim 21, wherein the first electrodes define an array of electrodes distributed over a pitch dimension, and removing a portion of the phase change material from each of the cavities comprises shielding a remaining portion of the phase change material such that the remaining portion defines an active region width on the order of the pitch dimension.

25. The method of claim 21, wherein depositing a phase change material comprises depositing in one of an atomic layer deposition and vapor deposition a thin film of phase change material onto exposed surfaces of the cavity.

26. The method of claim 21, wherein removing a portion of the phase change material comprises etching the phase change material in the cavities.

27. The method of claim 26, wherein etching the phase change material in the cavities comprises etching such that the at least one corner of the cavity partially shields the phase change material in the at least one corner from an etchant of the etch.

28. A method of fabricating a memory cell comprising:
depositing a dielectric layer over an electrode of a memory wafer;
forming a cavity in the dielectric layer that communicates with the electrode;
depositing a phase change material into the cavity, at least a portion of the phase change material defining a column extending a distance from the electrode to a top portion of the dielectric layer; and
providing means for selectively dimensioning a width the column to define a tetrahedron of phase change material extending from the electrode to the top portion of the dielectric layer.

29. The method of claim 28, wherein forming a cavity in the dielectric layer comprises etching the dielectric layer to define a vertical sidewall on either side of a corner within the cavity.

30. The method of claim 28, wherein depositing a phase change material into the cavity comprises depositing in one of an atomic layer deposition and vapor deposition a thin film of phase change material into a corner of the cavity.

31. The method of claim 30, wherein providing means for selectively dimensioning a width the column comprises etching portions of the column other than the phase change material in the corner of the cavity.

32. The method of claim 30, wherein the corner of the cavity partially shields the phase change material in the corner from an etchant of the etch.

33. The method of claim 30, wherein providing means for selectively dimensioning a width the column comprises planarizing a top portion of the tetrahedron to define an apex.
